(19) United States
(12) Patent Application Publication
(10) Pub. No.: US 2026/0050013 A1
(43) Pub. Date: Feb. 19, 2026

(54) CORELESS CURRENT SENSOR MODULE, CURRENT SENSOR MODULE, AND POWER MODULE

(71) Applicant: Asahi Kasei Microdevices Corporation, Tokyo (JP)

(72) Inventors: Takehiro MARUYAMA, Tokyo (JP); Taiga KYOSAKI, Tokyo (JP)

(21) Appl. No.: 19/296,935

(22) Filed: Aug. 12, 2025

(30) Foreign Application Priority Data
Aug. 19, 2024 (JP) 2024-137545
Feb. 7, 2025 (JP) 2025-019607

(51) Int. Cl. G01R 15/20

(52) U.S. Cl. CPC G01R 15/207

(57) ABSTRACT

A coreless current sensor module includes: a support member; a first current sensor which is mounted on a first surface of the support member and includes at least one magnetoelectric conversion element which outputs a signal corresponding to a magnitude of a magnetic field; an insulator which surrounds at least the first current sensor in a spaced-apart state as viewed in a first direction intersecting the first surface and at least partially overlaps with the first current sensor as viewed in a second direction extending along the first surface; and a first bus bar through which a current generating a magnetic field detected by the first current sensor flows, in which at least one of the insulator or the support member is present between the first current sensor and the first bus bar.

The contents of the following patent application(s) are incorporated herein by reference:
NO. 2024-137545 filed in JP on Aug. 19, 2024
NO. 2025-019607 filed in JP on Feb. 7, 2025.

### BACKGROUND

### 1. Technical Field

The present invention relates to a coreless current sensor module, a current sensor module, and a power module.

### 2. Related Art

Patent document 1 describes providing a sensor element at a position facing a housing in which a bus bar is embedded. Patent document 2 describes that a current sensor is arranged above or below a printed circuit board in which a conductor is embedded. Patent Document 3 describes that a bus bar and a magnetic detection element are arranged between two shield plates filled with a molding resin, the magnetic detection element being in a through opening of the bus bar.

### RELATED ART DOCUMENTS

### Patent Documents

Patent Document 1: Japanese Patent Application Publication No. 2019-70563
Patent Document 2: International Publication No. 2023/038725
Patent Document 3: Japanese Patent Application Publication No. 2017-187300

### BRIEF DESCRIPTION OF THE DRAWINGS

FIG. 1 is an external perspective view of a power module according to a first embodiment.

FIG. 2 is an external perspective view of the power module according to the first embodiment in a state where a substrate is removed.

FIG. 3 is an enlarged view of a current sensor portion illustrated in FIG. 2.

FIG. 4 is an external perspective view of the power module according to the first embodiment in a state where the substrate and an insulator are removed.

FIG. 5 is a plan view of the power module illustrated in FIG. 4 in a state where the substrate and the insulator are removed, as viewed from a positive side in a z axis direction.

FIG. 6 is a schematic cross-sectional view of a portion including a current sensor when the current sensor module according to the first embodiment is viewed in a y axis direction.

FIG. 7 is a schematic cross-sectional view of a portion including a current sensor 140 when a current sensor module according to a first modification is viewed in the y axis direction.

FIG. 8 is a schematic cross-sectional view of a portion including the current sensor 140 when a current sensor module according to a second modification is viewed in the y axis direction.

FIG. 9 is a schematic cross-sectional view of a portion including the current sensor 140 when a current sensor module according to a third modification is viewed in the y axis direction.

FIG. 10 is an external perspective view of a power module according to a second embodiment.

FIG. 11 is an external perspective view of the power module illustrated in FIG. 10 in a state where the insulator is removed.

FIG. 12 is a side view of the current sensor module according to the second embodiment as viewed in a positive direction of a y axis.

FIG. 13 is an external perspective view of a power module according to a third embodiment.

FIG. 14 is an external perspective view visualizing a part of an internal structure of the power module illustrated in FIG. 13.

FIG. 15 is an external perspective view of the power module illustrated in FIG. 13 in a state where the substrate is removed.

FIG. 16 is an enlarged view of a portion of the current sensor in FIG. 15.

FIG. 17 is a view illustrating a state where the substrate on which the current sensor is mounted is arranged on the insulator.

FIG. 18A is a plan view of a current sensor module according to a fourth embodiment.

FIG. 18B is a cross-sectional view taken along line A-A illustrated in FIG. 18B.

FIG. 19 is a view illustrating a state where another substrate electrically connected to a substrate included in the current sensor module illustrated in FIG. 18A is arranged above a bus bar.

FIG. 20 is a cross-sectional view of a current sensor module according to a first modification of the fourth embodiment.

FIG. 21 is a cross-sectional view of a current sensor module according to a second modification of the fourth embodiment.

FIG. 22 is a cross-sectional view of a current sensor module according to a third modification of the fourth embodiment.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to a solution of the invention.

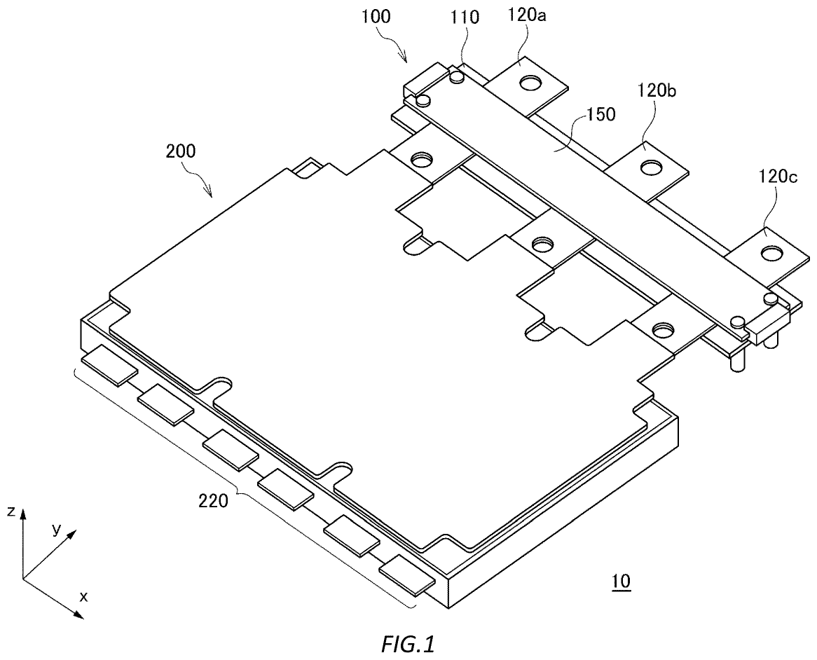

FIG. 1 is an external perspective view of a power module 10 according to a first embodiment. The power module 10 includes a current sensor module 100 and a power semiconductor unit 200. The power module 10 may be a three-phase inverter which converts direct current to three-phase alternating current. A three-phase alternating current output from the power module 10 may be supplied to a motor which is a three-phase alternating current motor. The motor may be a power source of a moving body. The power module 10 may be mounted on a moving body such as a hybrid vehicle or an electric vehicle. The power module 10, depending on its application, may be a single-phase inverter that converts direct current to alternating current.

In FIG. 1, coordinates are defined such that a direction parallel to a plane of paper and obliquely downward to right is an x axis direction, a direction parallel to the plane of the paper and obliquely upward to the right is a y axis direction, and a direction parallel to the plane of the paper and upward from bottom is a z axis direction. The z axis direction is an example of a first direction, the y axis direction is an example of a second direction, and the x axis direction is an example of a third direction.

The power semiconductor unit 200 includes a plurality of power semiconductors housed in an insulating enclosure 202, an input terminal portion 220 which is electrically connected to each of the plurality of power semiconductors and includes a plurality of input terminals exposed from the enclosure 202, and a plurality of bus bars 120a, 120b, and 120c which are electrically connected to each of the plurality of power semiconductors. The power semiconductor unit 200 includes, for example, six power semiconductors, the input terminal portion 220 which includes six input terminals electrically connected to the six power semiconductors, respectively, and three bus bars 120a, 120b, and 120c. The power semiconductor may be, for example, a MOSFET or an IGBT. Hereinafter, the plurality of bus bars 120a, 120b, and 120c may be collectively referred to as a bus bar 120. The bus bar 120 is an example of a first bus bar and a second bus bar. The input terminal portion 220 is an example of an input terminal portion of the power module 10. The bus bar 120 is an example of an output terminal portion of the power module 10.

The current sensor module 100 includes a substrate 150 on which a plurality of current sensors for measuring currents respectively flowing through the plurality of bus bars 120a, 120b, and 120c are mounted.

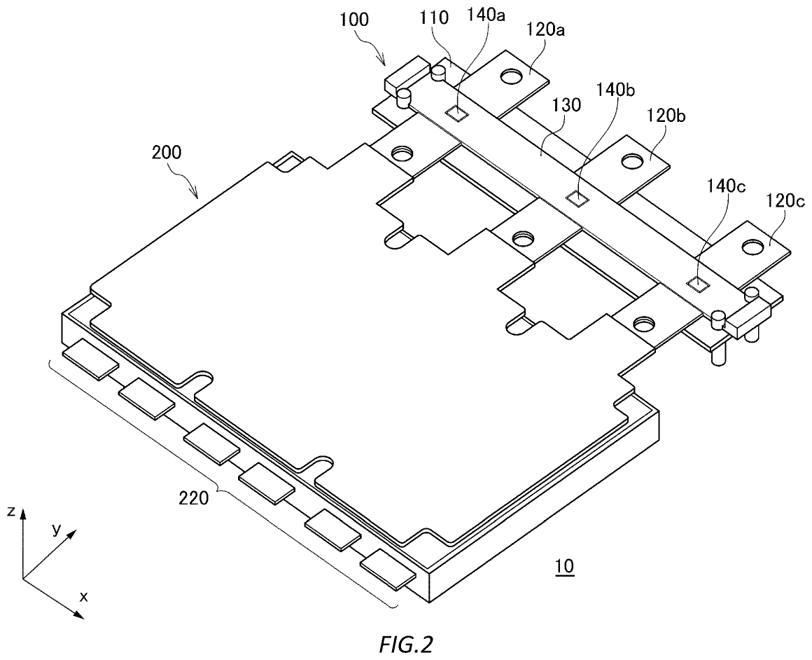

FIG. 2 is an external perspective view of the power module 10 in a state where the substrate 150 is removed. The current sensor module 100 includes a plurality of current sensors 140a, 140b, and 140c. The plurality of current sensors 140a, 140b, and 140c each outputs a signal corresponding to a magnitude of a magnetic field. Hereinafter, the plurality of current sensors 140a, 140b, and 140c may be collectively referred to as a current sensor 140. The plurality of current sensors 140a, 140b, and 140c are mounted on a surface of the substrate 150 facing the bus bar 120.

The current sensor 140 includes at least one magnetoelectric conversion element which outputs a signal corresponding to a magnitude of a magnetic field. The current sensor 140 may be a coreless current sensor, and the current sensor module 100 may be a coreless current sensor module. In the present specification, the coreless current sensor is a sensor which includes at least one magnetoelectric conversion element which outputs a signal corresponding to a magnitude of a magnetic field flowing through a conductor, and is a current sensor which does not include a magnetic core arranged around the magnetoelectric conversion element or arranged to surround a current conductor. The magnetic core has a role of amplifying a magnetic flux density penetrating the magnetoelectric conversion element.

The current sensor 140 may include, for example, two magnetoelectric conversion elements. The current sensor module 100 includes a signal processing circuit. For example, the signal processing circuit reduces a noise component included in output signals of the two magnetoelectric conversion elements and cancels a noise component due to a common external magnetic field, based on a difference between the output signals of the two magnetoelectric conversion elements, amplifies the output signals of the two magnetoelectric conversion elements in which the noise component is reduced, calculates a current value of a current flowing through the bus bar 120, based on the amplified output signals, and outputs an output signal indicating the current value. The magnetoelectric conversion element may be, for example, a Hall element which has a sensitivity axis in a direction intersecting a magnetic-sensitive surface and uses a Hall effect.

The current sensor 140 detects a magnetic field generated by the current flowing through the bus bar 120. Thus, in order to accurately measure the current flowing through the bus bar 120, the current sensor 140 is preferably arranged adjacent to the bus bar 120. However, since a high voltage of several hundred volts or more may be applied to the bus bar 120, when the current sensor 140 is excessively close to the bus bar 120, there is a possibility that insulation between the bus bar 120 and the current sensor 140 cannot be secured.

In this regard, the power module 10 according to the present embodiment includes an insulator 130 which is arranged at least between the bus bar 120 and the current sensor 140. Accordingly, while a distance between the current sensor 140 and the bus bar 120 is reduced, the insulation between the bus bar 120 and the current sensor 140 is secured.

Here, the insulator 130 may be, for example, an epoxy-based thermosetting resin to which silica is added, or a thermoplastic resin such as a liquid crystal polymer. The insulator 130 composed of such a material may expand and contract due to a temperature change. Thus, when the insulator 130 and the current sensor 140 are brought into close contact with each other, stress associated with expansion and contraction of the insulator 130 due to the temperature change is applied to the current sensor 140, which may affect current measurement of the current sensor 140. Such stress may cause a measurement error in an output value of the current sensor 140, for example.

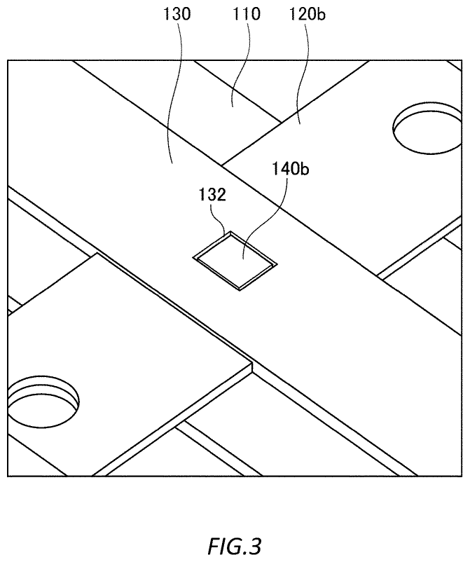

In this regard, in order to prevent the stress due to the expansion and contraction of the insulator 130 accompanying the temperature change from being applied to the current sensor 140, the insulator 130 is arranged with a gap 132 from the current sensor 140 (current sensor 140b) as illustrated in FIG. 3. The insulator 130 surrounds at least the current sensor 140 with the gap 132 therebetween, and at least partially overlaps with the current sensor 140 as viewed in the x axis direction or the y axis direction.

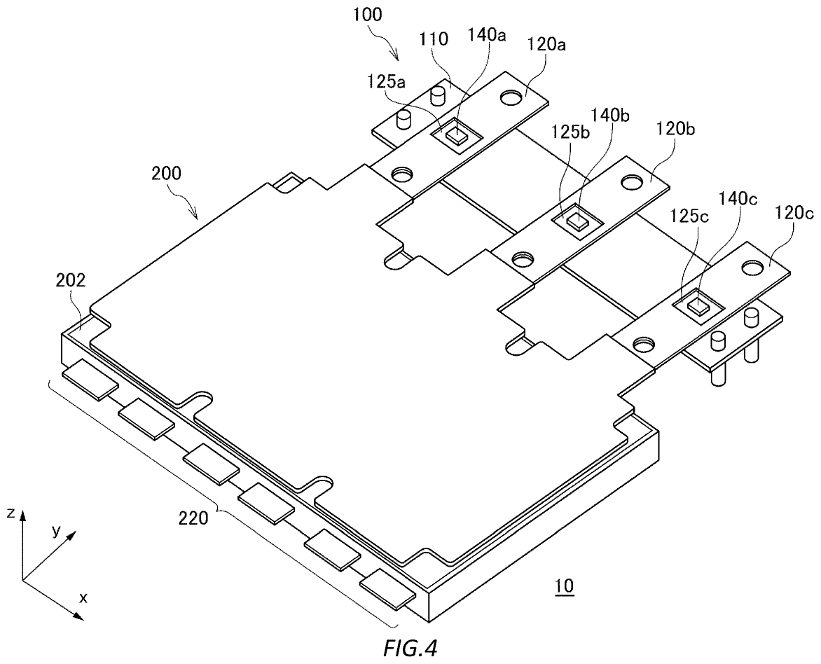

FIG. 4 is an external perspective view of the power module 10 in a state where the substrate 150 and the insulator 130 are removed. A support plate 110 supports each of the plurality of bus bars 120a, 120b, and 120c. The plurality of bus bars 120a, 120b, and 120c have through openings 125a, 125b, and 125c, respectively, and the current sensors 140a, 140b, and 140c are arranged in a plurality of through openings 125a, 125b, and 125c, respectively. A spacing between each of the current sensors 140a, 140b, and 140c and each of the bus bars 120a, 120b, and 120c may be more than 0 mm and equal to or less than 5 mm.

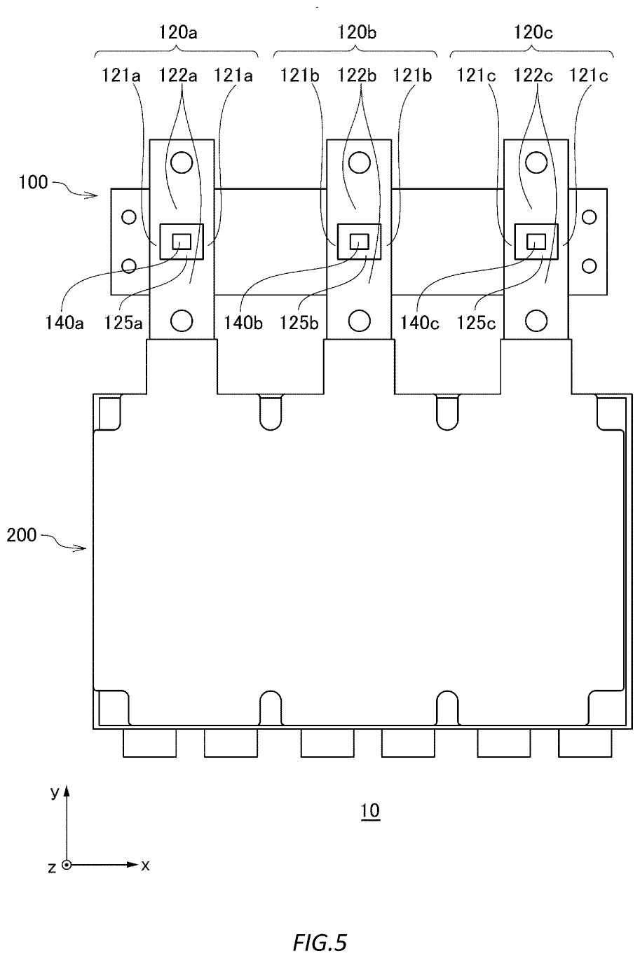

FIG. 5 is a plan view of the power module 10 illustrated in FIG. 4 in a state where the substrate 150 and the insulator 130 are removed, as viewed from a positive side in the z axis direction. The bus bar 120a, 120b, 120c includes a pair of conductor portions 121a, 121b, 121c which extend in the y axis direction and are arranged to face each other with the current sensor 140a, 140b, 140c interposed therebetween in the x axis direction, and a pair of coupling portions 122a, 122b, 122c which are respectively coupled to both ends of the pair of conductor portions 121a, 121b, 121c. The pair of conductor portions 121a, 121b, 121c are an example of a pair of first conductor portions and a pair of second conductor portions. The pair of coupling portions 122a, 122b, 122c are an example of a pair of first coupling portions and a pair of second coupling portions. The current sensor 140a, 140b, 140c is surrounded by the pair of conductor portions 121a, 121b, 121c and the pair of coupling portions 122a, 122b, 122c as viewed in the z axis direction.

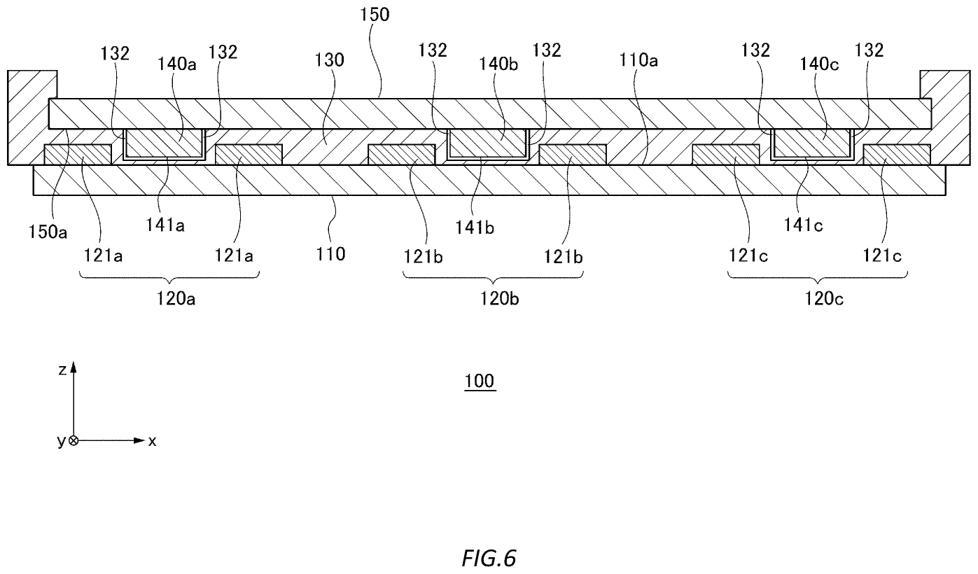

FIG. 6 is a schematic cross-sectional view of a portion including the current sensor 140 when the current sensor module 100 is viewed in the y axis direction.

The current sensors 140a, 140b, and 140c are arranged spaced apart in the x axis direction on a surface 150a of the substrate 150 facing the support plate 110. The surface 150a is an example of a first surface. The support plate 110 is arranged facing the surface 150a of the substrate 150, spaced apart in the z axis direction. On a surface 110a of the support plate 110 facing the substrate 150, the bus bars 120a, 120b, and 120c extending in the y axis direction are arranged so as to surround the current sensors 140a, 140b, and 140c as viewed in the z axis direction. The bus bars 120a, 120b, and 120c at least partially overlap with the current sensors 140a, 140b, and 140c as viewed in the x axis direction or the y axis direction. The bus bars 120a, 120b, and 120c are arranged spaced apart from the substrate 150 in the z axis direction, and a current generating a magnetic field detected by the current sensors 140a, 140b, and 140c flows therethrough.

Between the substrate 150 and the support plate 110, the insulator 130 is arranged with the gap 132 from the current sensors 140a, 140b, and 140c. The insulator 130 is in contact with the bus bars 120a, 120b, and 120c. On the other hand, the insulator 130 is not in contact with the current sensors 140a, 140b, and 140c. The insulator 130 is arranged at least between each pair of conductor portions 121a, 121b, 121c and the current sensor 140a, 140b, 140c, with the gap 132 from the current sensor 140a, 140b, 140c. The insulator 130 surrounds at least the current sensors 140a, 140b, and 140c with the gap 132 therebetween as viewed in the z axis direction, and at least partially overlaps with the current sensors 140a, 140b, and 140c as viewed in the x axis direction or the y axis direction. The insulator 130 is further arranged in a spacing between the substrate 150 and each pair of conductor portions 121a, 121b, 121c. The insulator is further arranged so as to cover surfaces 141a, 141b, and 141c of the current sensors 140a, 140b, and 140c opposite to the surface 150a where the current sensors 140a, 140b, and 140c are mounted on the substrate 150, spaced apart from the current sensors 140a, 140b, and 140c in the z axis direction.

The bus bars 120 are arranged spaced apart in the x axis direction on the support plate 110, and the insulator 130 in which an opening or a groove is formed in a location where the current sensor 140 is to be arranged is further arranged on the bus bars 120 and the support plate 110. Thereafter, the substrate 150 on which the current sensor 140 is mounted is arranged on the insulator 130 such that the current sensor 140 is accommodated in the opening or the groove. Accordingly, the current sensor module 100 may be configured.

As described above, according to the current sensor module 100 of the first embodiment, the insulator 130 is provided between the current sensor 140 and the bus bar 120, so that it is possible to secure the insulation between the bus bar 120 and the current sensor 140 while reducing the distance between the current sensor 140 and the bus bar 120. Moreover, since spacing is provided between the insulator 130 and the current sensor 140, it is possible to prevent the stress, which is caused by expansion or contraction of the insulator 130 due to a temperature change caused by a change in environment around the power module 10 or application of a large current to the bus bar, from being transmitted to the current sensor 140, and it is possible to prevent the stress from affecting measurement of the current sensor 140.

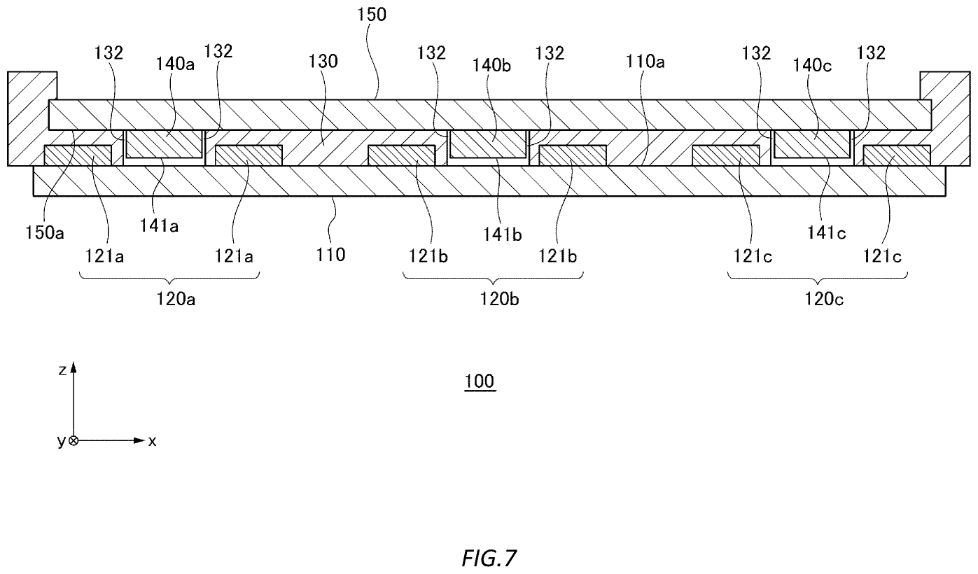

FIG. 7 is a schematic cross-sectional view of a portion including the current sensor 140 when the current sensor module 100 according to a first modification is viewed in the y axis direction. The current sensor module 100 illustrated in FIG. 7 is different from the current sensor module 100 illustrated in FIG. 6 in that the insulator 130 is not arranged so as to cover the surfaces 141a, 141b, and 141c of the current sensors 140a, 140b, and 140c opposite to the surface 150a where the current sensors 140a, 140b, and 140c are mounted on the substrate 150, spaced apart from the current sensors 140a, 140b, and 140c in the z axis direction. That is, the insulator 130 has openings which expose the surfaces 141a, 141b, and 141c of the current sensors 140a, 140b, and 140c opposite to the surfaces where the current sensors 140a, 140b, and 140c are mounted on the substrate 150. The insulator 130 may have a gap from the bus bar 120. That is, the insulator 130 may include a first insulator which surrounds the current sensor 120a with a gap therebetween as viewed in the z axis direction and at least partially overlaps with the current sensor 120a as viewed in the x axis direction, a second insulator which surrounds the current sensor 120b with a gap therebetween as viewed in the z axis direction and at least partially overlaps with the current sensor 120b as viewed in the x axis direction, and a third insulator which surrounds the current sensor 120c with a gap therebetween as viewed in the z axis direction and at least partially overlaps with the current sensor 120c as viewed in the x axis direction. As viewed in the z axis direction, gaps may be provided at least partially between the first insulator and the second insulator and between the second insulator and the third insulator. The first insulator and the second insulator may be separated from each other, and the second insulator and the third insulator may be separated from each other. The first insulator, the second insulator, and the third insulator may be individual insulators. The first insulator, the second insulator, and the third insulator may be at least partially coupled. The first insulator, the second insulator, and the third insulator may be integrally configured.

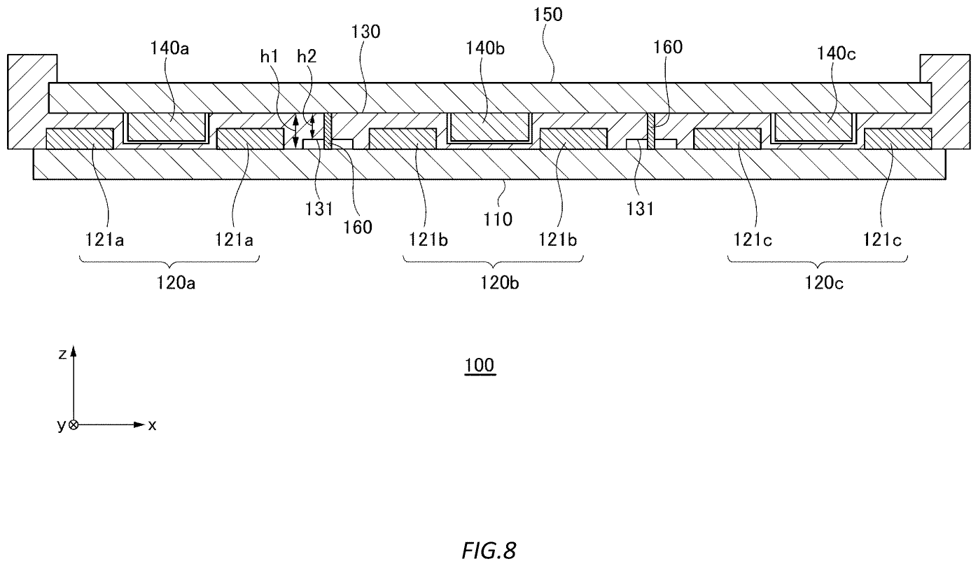

FIG. 8 is a schematic cross-sectional view of a portion including the current sensor 140 when the current sensor module 100 according to a second modification is viewed in the y axis direction. The current sensor module 100 according to the second modification is different from the current sensor module 100 illustrated in FIG. 6 in that steps 131 are provided in the insulator 130 between the bus bar 120a and the bus bar 120b and between the bus bar 120b and the bus bar 120c. That is, in the current sensor module 100 according to the second modification, a portion of the insulator 130 arranged between the bus bar 120a and the bus bar 120b and a portion of the insulator 130 between the bus bar 120b and the bus bar 120c each include a portion h1 having a first thickness from the surface 150a of the substrate 150 and a portion h2 having a second thickness, which is different from the first thickness h1, from the surface 150a of the substrate 150. Accordingly, creepage distances between the bus bar 120a and the bus bar 120b and between the bus bar 120b and the bus bar 120c can be increased, and insulation between the bus bar 120a and the bus bar 120b and between the bus bar 120b and the bus bar 120c can be further secured.

Further, the current sensor module 100 according to the second modification is different from the current sensor module 100 illustrated in FIG. 6 in that wall portions 160, which each include a magnetic body protruding from the surface 150a of the substrate 150, are further included between the bus bar 120a and the bus bar 120b and between the bus bar 120b and the bus bar 120c. The wall portion 160 may be composed of a magnetic shield plate containing a soft magnetic material containing an iron group element such as Fe, Co, or Ni. That is, in the present specification, the current sensor module 100 according to the second modification is not a coreless current sensor module, and the current sensor 140 in the current sensor module 100 is not a coreless current sensor. Accordingly, the current sensor 140 can be hardly affected by a magnetic field generated by a current flowing through the bus bar 120 other than the bus bar 120 through which a current to be measured flows.

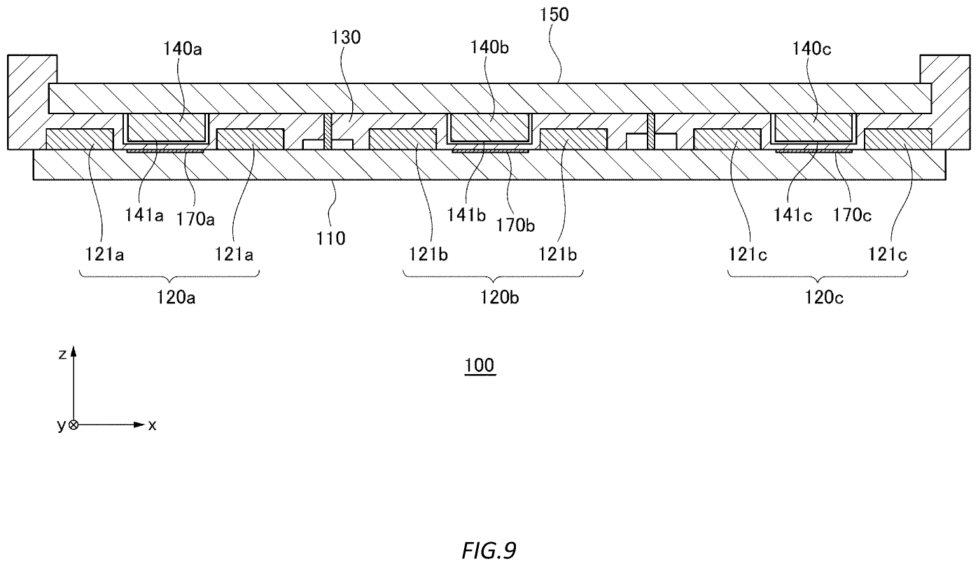

FIG. 9 is a schematic cross-sectional view of a portion including the current sensor 140 when the current sensor module 100 according to a third modification is viewed in the y axis direction. The current sensor module 100 according to the third modification is different from the current sensor module 100 illustrated in FIG. 6 in that magnetism collecting plates 170a, 170b, and 170c provided spaced apart from the current sensors 140a, 140b, and 140c in the z axis direction are included at positions facing the surfaces 141a, 141b, and 141c of the current sensors 140a, 140b, and 140c opposite to the surface 150a where the current sensors 140a, 140b, and 140c are mounted on the substrate 150. That is, in the present specification, the current sensor module 100 according to the second modification is not a coreless current sensor module, and the current sensor 140 in the current sensor module 100 is not a coreless current sensor. The magnetism collecting plates 170a, 170b, and 170c may be composed of a ferrite substrate, a sheet obtained by mixing a magnetic powder such as a ferrite powder with resin, and a magnetic alloy such as an Fe—Si-based alloy, an Fe-based or Co-based amorphous alloy, or an ultrafine crystal soft magnetic alloy. By providing the magnetism collecting plates 170a, 170b, and 170c, the current sensors 140a, 140b, and 140c can easily detect the magnetic field generated by the current flowing through the bus bars 120a, 120b, and 120c. The magnetism collecting plates 170a, 170b, and 170c may be incorporated in the insulator 130, or may be provided between the insulator 130 and the support plate 110. As illustrated in FIG. 9, when the insulator 130 has openings which expose the surfaces 141a, 141b, and 141c of the surface where the current sensors 140a, 140b, and 140c opposite to the surface where the current sensors 140a, 140b, and 140c are mounted on the substrate 150, the magnetism collecting plates 170a, 170b, and 170c may be provided at positions of the support plate 110 facing the surfaces 141a, 141b, and 141c of the current sensors 140a, 140b, and 140c.

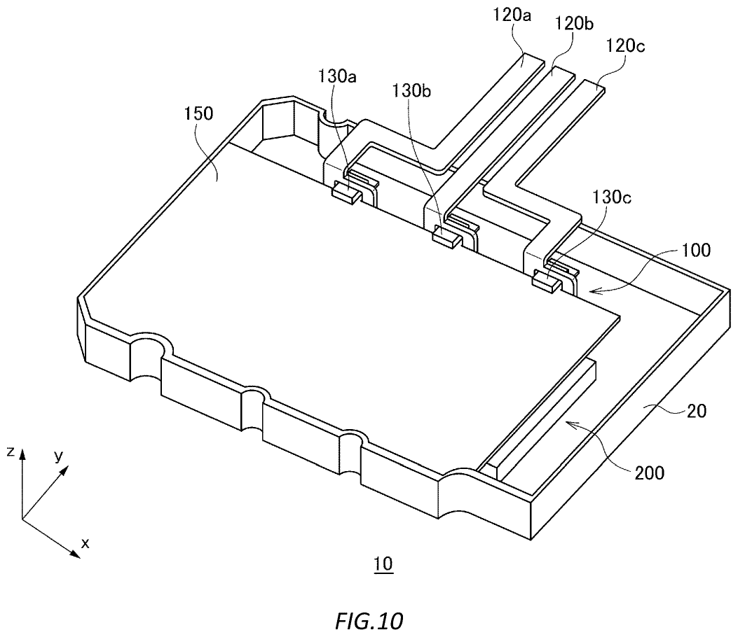

FIG. 10 is an external perspective view of the power module 10 according to a second embodiment. In the power module 10 according to the second embodiment, shapes of the bus bars 120a, 120b, and 120c are different from shapes of the bus bars 120a, 120b, and 120c of the power module 10 according to the first embodiment. In the power module 10 according to the second embodiment, a positional relationship between the bus bars 120a, 120b, and 120c and the current sensors 140a, 140b, and 140c is different from a positional relationship between the bus bars 120a, 120b, and 120c and the current sensors 140a, 140b, and 140c of the power module 10 according to the first embodiment.

In the power module 10 according to the second embodiment, insulators 130a, 130b, and 130c are provided on the substrate 150 so as to cover the current sensors 140a, 140b, and 140c (not illustrated in FIG. 10).

The current sensor module 100 and the power semiconductor unit 200 are accommodated in an outer frame 20.

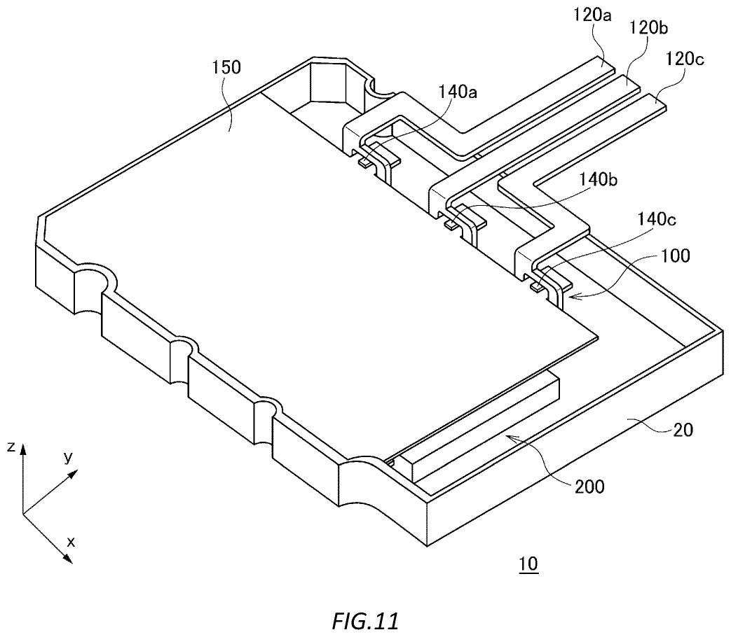

FIG. 11 is an external perspective view of the power module 10 illustrated in FIG. 10 in a state where the insulators 130a, 130b, and 130c are removed. That is, FIG. 11 is an external perspective view of the power module 10 in a state where the current sensors 140a, 140b, and 140c arranged spaced apart along the x axis direction on the substrate 150 are exposed.

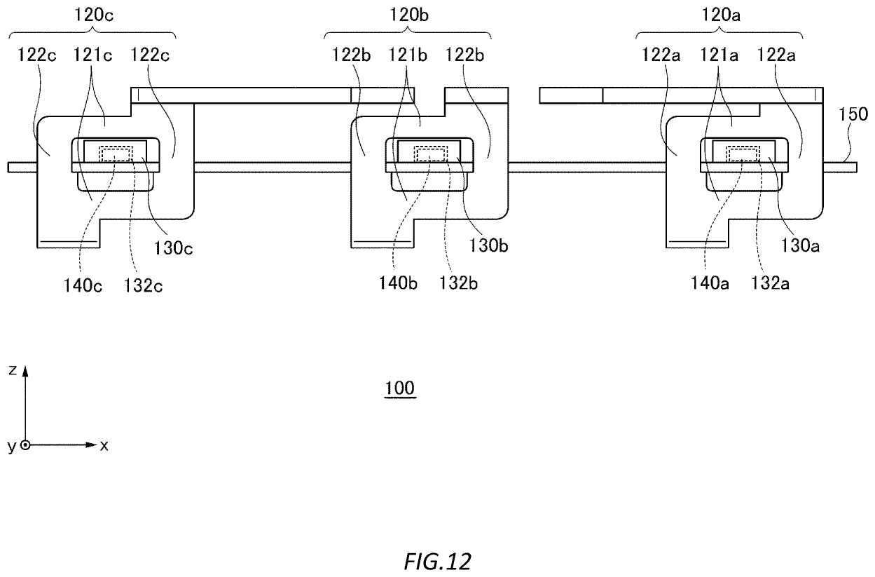

FIG. 12 is a side view of the current sensor module 100 according to the second embodiment as viewed in a positive direction of a y axis. The bus bar 120a, 120b, 120c includes a pair of conductor portions 121a, 121b, 121c which extend in the z axis direction and are arranged to face each other with the current sensor 140a, 140b, 140c interposed therebetween in the x axis direction. Further, the bus bar 120a, 120b, 120c includes the pair of coupling portions 122a, 122b, 122c which are respectively coupled to both ends of the pair of conductor portions 121a, 121b, 121c. The current sensor 140a, 140b, 140c is surrounded by the pair of conductor portions 121a, 121b, 121c and the pair of coupling portions 122a, 122b, 122c as viewed in the y axis direction. As viewed in the x axis direction, the pair of conductor portions 121a, 121b, 121c and the current sensors 140a, 140b, 140c at least partially overlap with each other. The spacing between the current sensor 140a, 140b, 140c and the bus bar 120a, 120b, 120c may be more than 0 mm and equal to or less than 5 mm.

The insulators 130a, 130b, and 130c at least surround the current sensors 140a, 140b, and 140c with the gaps 132a, 132b, and 132c therebetween as viewed in the z axis direction, and at least partially overlap with the current sensors 140a, 140b, and 140c as viewed in the x axis direction or the y axis direction.

The insulator 130a, 130b, 130c are not in contact with the current sensors 140a, 140b, 140c. The insulator 130a, 130b, 130c is arranged at least between the pair of conductor portions 121a, 121b, 121c and the current sensor 140a, 140b, 140c, with the gap 132a, 132b, 132c from the current sensor 140a, 140b, 140c.

As described above, according to the current sensor module 100 of the second embodiment, the insulator 130 is provided between the current sensor 140 and the bus bar 120, so that it is possible to secure the insulation between the bus bar 120 and the current sensor 140 and while reducing the distance between the current sensor 140 and the bus bar 120. Moreover, since a spacing is provided between the insulator 130 and the current sensor 140, it is possible to prevent the stress, which is caused by the expansion or contraction of the insulator 130 due to the temperature change caused by the change in the environment around the power module 10, from being transmitted to the current sensor 140, and it is possible to prevent the stress from affecting the measurement of the current sensor 140.

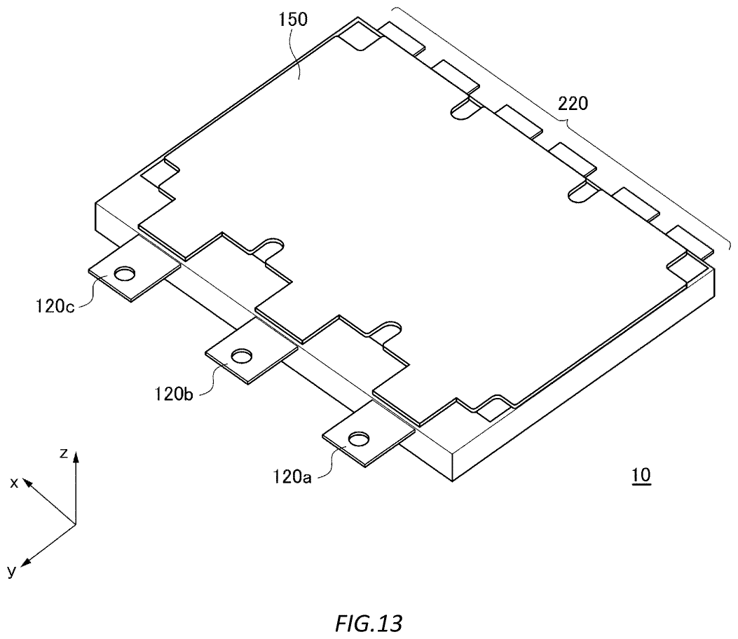

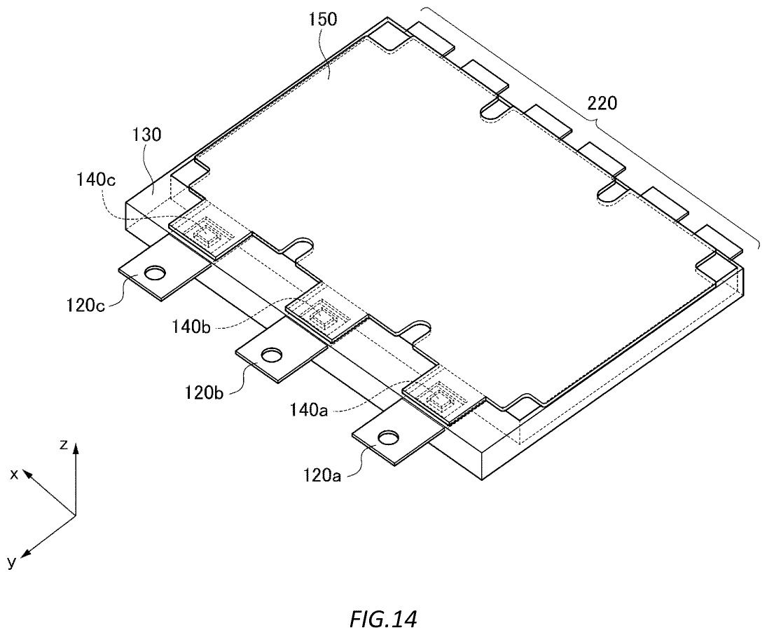

FIG. 13 is an external perspective view of the power module 10 according to a third embodiment. FIG. 14 is an external perspective view visualizing a part of an internal structure of the power module 10 illustrated in FIG. 13. The power module 10 according to the third embodiment is different from the power module 10 according to the first embodiment in that the substrate 150 on which the current sensors 140a, 140b, and 140c are mounted also serves as a substrate on which a power semiconductor constituting the power semiconductor unit 200 is mounted.

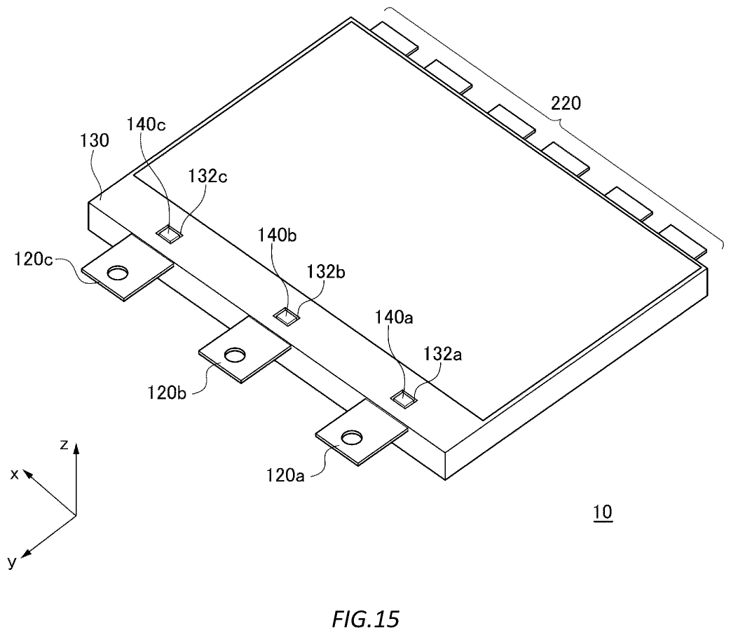

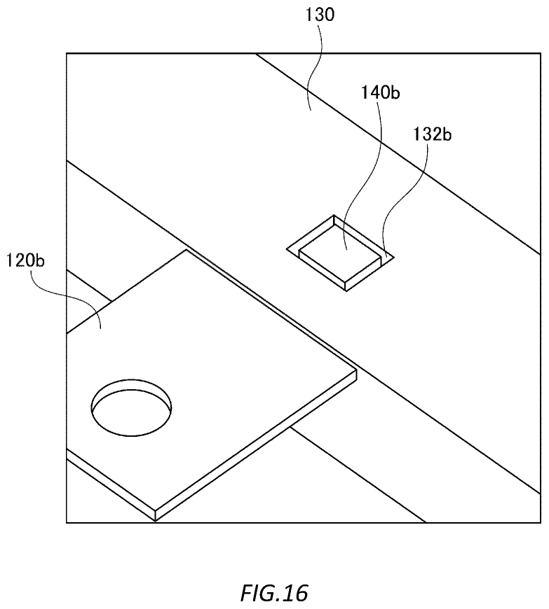

FIG. 15 is an external perspective view of the power module 10 illustrated in FIG. 13 in a state where the substrate 150 is removed. FIG. 16 is an enlarged view of a portion of the current sensor 140b in FIG. 15. The insulator 130 may be a part of a sealing portion composed of a molding resin which seals each circuit constituting the power module 10 including a circuit such as a power semiconductor constituting the power semiconductor unit 200. In the insulator 130, grooves having widths larger than those of the current sensors 140a, 140b, and 140c are formed at positions where the current sensors 140a, 140b, and 140c are arranged. Accordingly, the gaps 132a, 132b, and 132c are provided between the current sensors 140a, 140b, and 140c and the insulator 130.

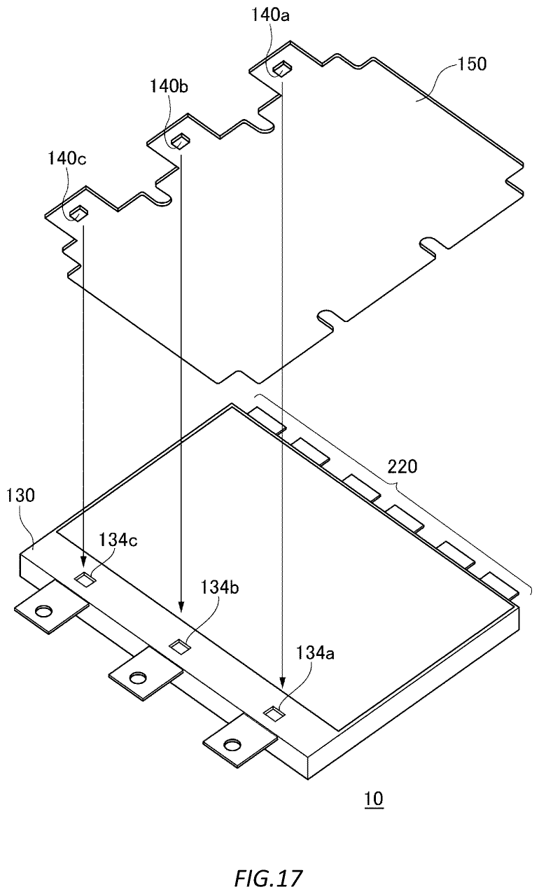

FIG. 17 illustrates a state where the substrate 150 on which the current sensors 140a, 140b, and 140c are mounted is arranged on the insulator 130. The insulator 130 is provided with openings 134a, 134b, and 134c larger than the current sensors 140a, 140b, and 140c at the positions where the current sensors 140a, 140b, and 140c are arranged. Then, the substrate 150 on which the current sensors 140a, 140b, and 140c are mounted is arranged and fixed on the insulator 130 such that the current sensors 140a, 140b, and 140c are accommodated in the openings 134a, 134b, and 134c.

Note that in the third embodiment, an example has been described in which a control substrate constituting the current sensor module 100 and a control substrate constituting the power semiconductor unit 200 are constituted by one substrate 150 in the insulator 130 constituting the sealing portion. However, in the insulator 130, separate substrates may be arranged for the control substrate constituting the current sensor module 100 and the control substrate constituting the power semiconductor unit 200.

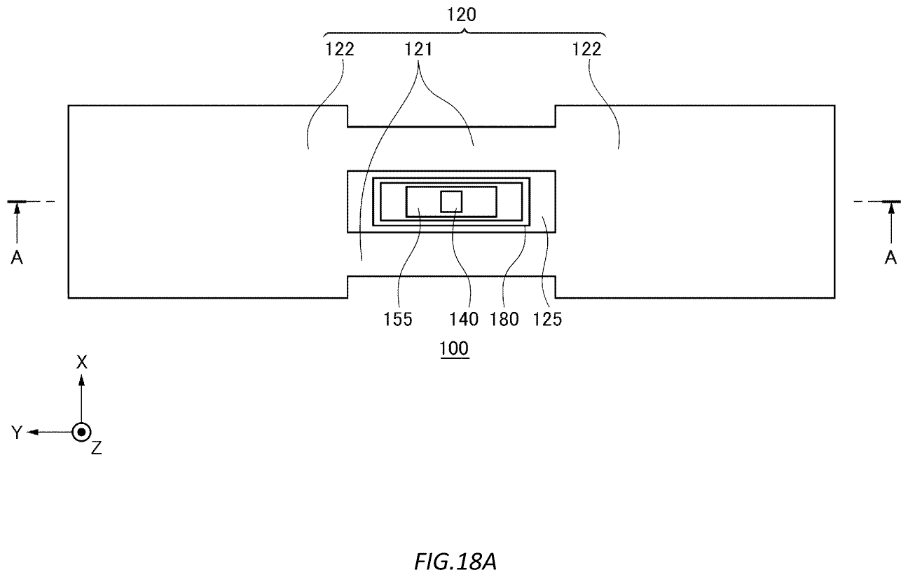

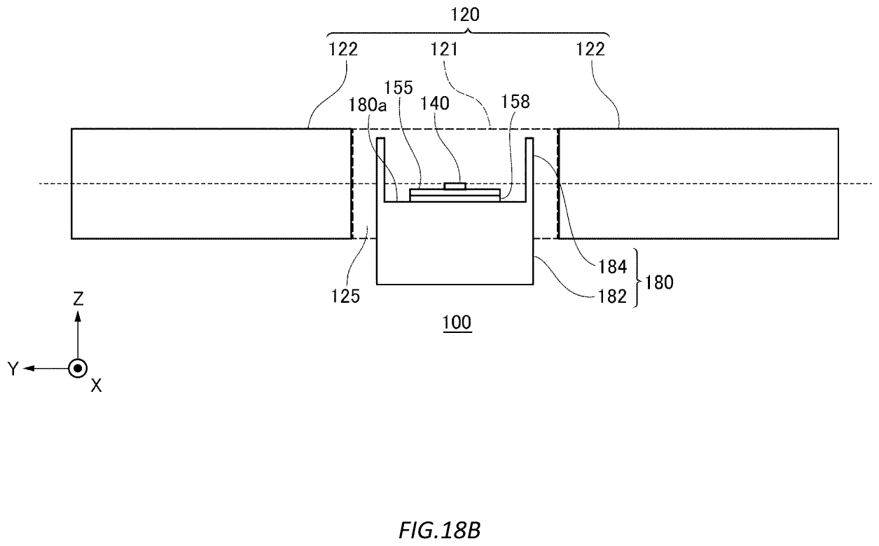

FIG. 18A is a plan view of the current sensor module 100 according to a fourth embodiment. FIG. 18B is a cross-sectional view taken along line A-A illustrated in FIG. 18B. For example, the power module 10 illustrated in FIG. 1 may include the current sensor module 100 according to the fourth embodiment.

The current sensor module 100 includes the bus bar 120 and the current sensor 140 which measures the current flowing through the bus bar 120. The current sensor 140 may be a coreless current sensor, and the current sensor module 100 may be a coreless current sensor module. The current sensor module 100 may include a plurality of bus bars 120 and the current sensor 140 which measures currents flowing through the plurality of bus bars 120.

The bus bar 120 includes a pair of conductor portions 121 which extend in the y axis direction and are arranged to face each other with the current sensor 140 interposed therebetween in the x axis direction, and a pair of coupling portions 122 which are coupled to both ends of the pair of conductor portions 121. The pair of conductor portions 121 are an example of the pair of first conductor portions. The pair of coupling portions 122 are an example of the pair of first coupling portions. The current sensor 140 has a through opening 125 surrounded by the pair of conductor portions 121 and the pair of coupling portions 122 as viewed in the z axis direction.

The current sensor module 100 further includes a support member 180 which supports the current sensor 140. The support member 180 includes a base 182 and a surrounding wall 184 arranged so as to surround a surface 180a of the base 182. The base 182 and the surrounding wall 184 may be integrally configured. The support member 180 may be composed of an insulator. The insulator may be resin, for example, an epoxy-based thermosetting resin to which silica is added, or a thermoplastic resin such as a liquid crystal polymer. The surrounding wall 184 is an example of a first portion of the support member 180.

A substrate 155 is provided on the surface 180a of the base 182 via an adhesive layer 158, and the current sensor 140 is provided on the substrate 155. The adhesive layer 158 may be a die attach film. The surrounding wall 184 is provided on the surface 180a of the base 182 so as to surround the substrate 155 and the current sensor 140. The base 182 may be fixed to the outer frame 20 which accommodates the current sensor module 100 as illustrated in FIG. 11. The base 182 and the substrate 155 are examples of a second portion of the support member 180.

The base 182 may be used to adjust a height of the current sensor 140. In order to accurately measure the current flowing through the bus bar 120, the current sensor 140 is preferably arranged at a position traversed by a plane passing through centers of the pair of first conductor portions 121 and the pair of first coupling portions 122 in the z axis direction. A magnetic-sensitive surface of the current sensor 140 may be present on the plane passing through the centers of the pair of first conductor portions 121 and the pair of first coupling portions 122 in the z axis direction. In the current sensor 140, in order to more accurately measure the current flowing through the bus bar 120, it is more preferable that the magnetic-sensitive surface of the current sensor 140 is arranged in a central portion in the through opening 125 of the bus bar 120. For example, when the current sensor 140 includes, as the magnetoelectric conversion element, a Hall element which is a longitudinal magnetic field detection element, the central portion in the through opening 125 of the bus bar 120 has a higher magnetic flux density in the z axis direction in a magnetic flux generated by a current flowing through the pair of conductor portions 121. Thus, it is preferable that the magnetic-sensitive surface of the current sensor 120 is arranged in the central portion of the through opening 125 of the bus bar 120.

The surrounding wall 184 is arranged on the surface 180a of the base 182 so as to surround the substrate 155 and the current sensor 140 spaced apart from the current sensor 140 as viewed in the z axis direction. A presence of the surrounding wall 184 as an insulator between the bus bar 120 and the current sensor 140 makes it possible to secure the insulation between the bus bar 120 and the current sensor 140. The presence of the surrounding wall 184 makes it possible to secure the insulation between the bus bar 120 and the current sensor 140 while reducing the distance between the current sensor 140 and the bus bar 120.

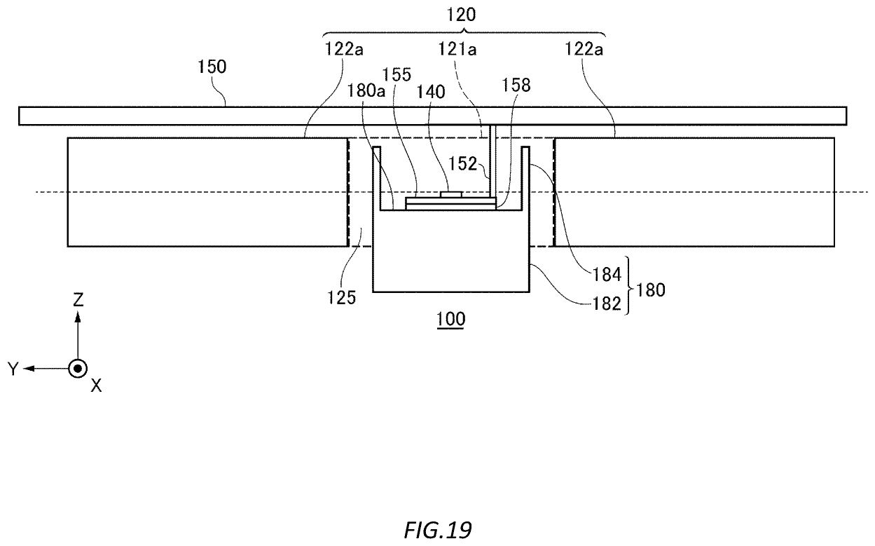

FIG. 19 illustrates a state where the substrate 155 electrically connected to the substrate 150 included in the current sensor module 100 illustrated in FIG. 18A is arranged above the bus bar 120. The substrate 155 may be electrically connected via a wire harness 152 to the substrate 150 which is a main substrate on which a control circuit which controls the power module 10 is mounted.

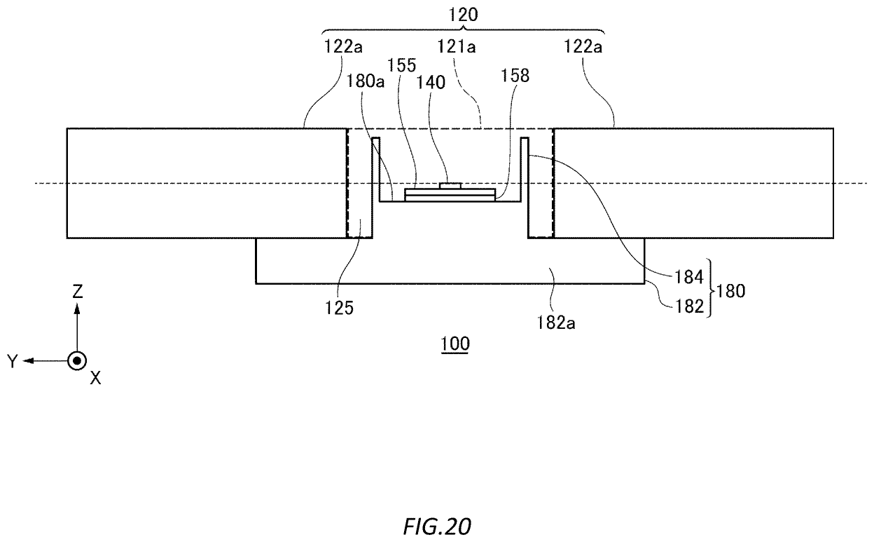

FIG. 20 is a cross-sectional view of the current sensor module 100 according to a first modification of the fourth embodiment. The current sensor module 100 according to the first modification is different from the current sensor module 100 illustrated in FIG. 18B in that the base 182 has a protruding portion 182a so as to support the bus bar 120.

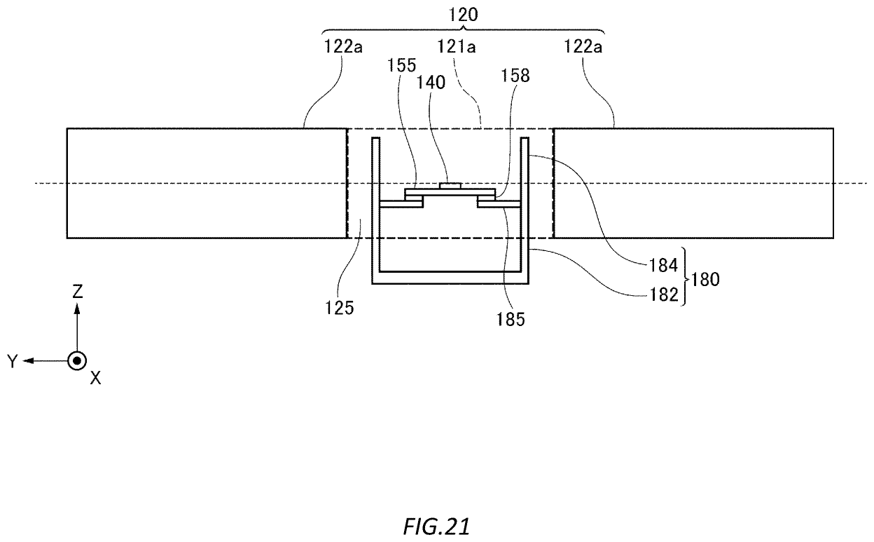

FIG. 21 is a cross-sectional view of the current sensor module 100 according to a second modification of the fourth embodiment. The current sensor module 100 according to the first modification is different from the current sensor module 100 of the fourth embodiment in a structure of the support member 180.

In the current sensor module 100 according to the second modification, the base 182 is hollow. The support member 180 constitutes a box-shaped structural body by the base 182 and the surrounding wall 184. The support member 180 has a shelf portion 185 for supporting the substrate 155 on an inner wall portion. The substrate 155 is fixed to the shelf portion 185 via the adhesive layer 158.

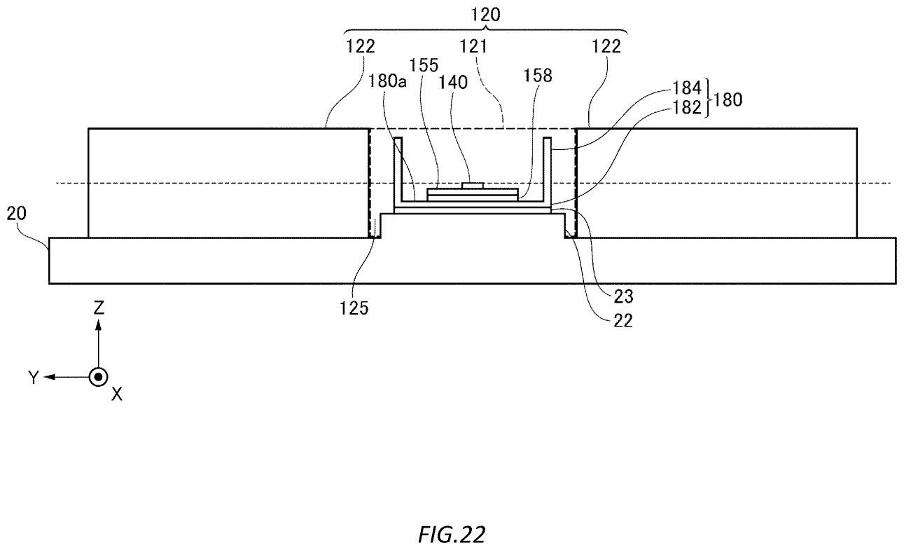

FIG. 22 is a cross-sectional view of the current sensor module 100 according to a third modification of the fourth embodiment. The current sensor module 100 according to the third modification is different from the current sensor module 100 of the fourth embodiment in the structure of the support member 180.

In the third modification, the support member 180 is fixed via the adhesive layer 23 onto a protrusion 22 of a bottom surface of the outer frame 20 which is an enclosure which accommodates the power module 10. The protrusion 22 protrudes into the through opening 125 of the bus bar 120. The adhesive layer 23 may be a die attach film. Similarly to the power module 10 of the fourth embodiment, the support member 180 includes the base 182 and the surrounding wall 184. However, since the protrusion 22 is present, a thickness of the base 182 may be thinner than that of the base 182 of the fourth embodiment. The substrate 155 on which the current sensor 140 is mounted may be fixed to the base 182 via the adhesive layer 158. The support member 180 may be provided on a heat sink instead of the outer frame 20. The support member 180 may be configured integrally with the heat sink. When the support member 180 is provided on the heat sink, an insulating member may be provided between the heat sink and the bus bar 120.

As described above, according to the current sensor module 100 according to the first to third modifications of the fourth embodiment, similarly to the current sensor module 100 of the fourth embodiment, the presence of the surrounding wall 184 as the insulator between the bus bar 120 and the current sensor 140 makes it possible to secure the insulation between the bus bar 120 and the current sensor 140. The presence of the surrounding wall 184 makes it possible to secure the insulation between the bus bar 120 and the current sensor 140 while reducing the distance between the current sensor 140 and the bus bar 120.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### (Item 1)

A coreless current sensor module including
a support member;
a first current sensor which is mounted on a first surface of the support member and includes at least one magnetoelectric conversion element which outputs a signal corresponding to a magnitude of a magnetic field;
an insulator which surrounds at least the first current sensor with a gap therebetween as viewed in a first direction intersecting the first surface and at least partially overlaps with the first current sensor as viewed in a second direction extending along the first surface; and
a first bus bar through which a current generating a magnetic field detected by the first current sensor flows, wherein
at least one of the insulator or the support member is present between the first current sensor and the first bus bar.

### (Item 2)

The coreless current sensor module according to item 1, wherein
the support member is a substrate,
the first bus bar is arranged spaced apart from the substrate, and
the insulator is present between the first current sensor and the first bus bar.

### (Item 3)

The coreless current sensor module according to item 2, wherein
a direction intersecting the second direction along the substrate is defined as a third direction, and
the first bus bar at least partially overlaps with the first current sensor as viewed in the first direction or the third direction.

### (Item 4)

The coreless current sensor module according to item 2, wherein
the first bus bar includes a pair of first conductor portions which extend in the second direction and are arranged to face each other with the first current sensor interposed therebetween in a third direction intersecting the second direction along the substrate, and
the insulator is arranged at least between each of the pair of first conductor portions and the first current sensor, with a gap from the first current sensor.

### (Item 5)

The coreless current sensor module according to item 4, wherein
the first bus bar includes a pair of first coupling portions which are respectively coupled to both ends of the pair of first conductor portions and
the first current sensor is surrounded by the pair of first conductor portions and the pair of first coupling portions as viewed in the first direction.

### (Item 6)

The coreless current sensor module according to item 4, wherein the insulator is further arranged between the substrate and each of the pair of first conductor portions.

### (Item 7)

The coreless current sensor module according to item 2, wherein the first bus bar and the insulator are in contact with each other.

### (Item 8)

The coreless current sensor module according to item 5, wherein the insulator is further arranged so as to cover a surface of the first current sensor opposite to a surface where the first current sensor is mounted on the substrate, with a gap from the first current sensor in the first direction.

### (Item 9)

The coreless current sensor module according to item 5, wherein the insulator has an opening which exposes a surface of the first current sensor opposite to a surface where the first current sensor is mounted on the substrate.

### (Item 10)

The coreless current sensor module according to item 2, wherein
the first bus bar includes a pair of first conductor portions which extend in a third direction intersecting the second direction along the substrate and are arranged to face each other with the first current sensor interposed therebetween in the first direction, and
the insulator is further arranged between one of the pair of first conductor portions and the first current sensor, with a gap from the first current sensor.

### (Item 11)

The coreless current sensor module according to item 10, wherein
the first bus bar includes a pair of first coupling portions which are respectively coupled to both ends of the pair of first conductor portions, and
the first current sensor is surrounded by the pair of first conductor portions and the pair of first coupling portions as viewed in the second direction.

### (Item 12)

The coreless current sensor module according to item 2, further including:

a second current sensor which is mounted on the first surface of the substrate and includes at least one magnetoelectric conversion element which outputs a signal corresponding to a magnitude of a magnetic field; and
a second bus bar which is arranged spaced apart from the substrate and through which a current generating a magnetic field detected by the second current sensor flows, wherein the insulator further surrounds the second current sensor with a gap therebetween as viewed in the first direction, and at least partially overlaps with the second current sensor as viewed in the second direction.

### (Item 13)

The coreless current sensor module according to item 12, wherein
the first bus bar includes a pair of first conductor portions which extend in the second direction and are arranged to face each other with the first current sensor interposed therebetween in a third direction intersecting the second direction along the first surface,
the second bus bar includes a pair of second conductor portions which extend in the second direction and are arranged to face each other with the second current sensor interposed therebetween in the third direction, and
the insulator is arranged at least between each of the pair of first conductor portions and the first current sensor, with a gap from the first current sensor, and is arranged at least between each of the pair of second conductor portions and the second current sensor, with a gap from the second current sensor.

### (Item 14)

The coreless current sensor module according to item 13, wherein
the first bus bar includes a pair of first coupling portions which are respectively coupled to both ends of the pair of first conductor portions,
the second bus bar includes a pair of second coupling portions which are respectively coupled to both ends of the pair of second conductor portions,
the first current sensor is surrounded by the pair of first conductor portions and the pair of first coupling portions as viewed in the first direction, and
the second current sensor is surrounded by the pair of second conductor portions and the pair of second coupling portions as viewed in the first direction.

### (Item 15)

The coreless current sensor module according to item 12, wherein the first current sensor and the second current sensor are arranged side by side in a third direction intersecting the second direction along the substrate.

### (Item 16)

The coreless current sensor module according to item 12, wherein a portion of the insulator arranged between the first bus bar and the second bus bar includes a portion having a first thickness from the first surface of the substrate and a portion having a second thickness, which is different from the first thickness, from the first surface of the substrate.

### (Item 17)

The coreless current sensor module according to item 12, wherein
the insulator includes
a first insulator which surrounds the first current sensor with a gap therebetween as viewed in the first direction and at least partially overlaps with the first current sensor as viewed in the second direction, and
a second insulator which surrounds the second current sensor with a gap therebetween as viewed in the first direction and at least partially overlaps with the second current sensor as viewed in the second direction, and
as viewed in the first direction, a gap is provided at least partially between the first insulator and the second insulator.

### (Item 18)

The coreless current sensor module according to item 2, wherein a spacing between the first current sensor and the first bus bar is more than 0 mm and equal to or less than 5 mm.

### (Item 19)

A coreless current sensor module including:
a substrate;
a first current sensor which is mounted on a first surface of the substrate and includes at least one magnetoelectric conversion element which outputs a signal corresponding to a magnitude of a magnetic field;
a first bus bar which includes a pair of first conductor portions which extend in a second direction extending along the substrate or in a third direction intersecting the second direction along the substrate and are arranged to face each other with the first current sensor interposed therebetween as viewed in a first direction intersecting the substrate or in the second direction, and is arranged spaced apart from the substrate, and through which a current generating a magnetic field detected by the first current sensor flows; and
an insulator which is arranged at least between the pair of first conductor portions and the first current sensor, with a gap from the first current sensor, as viewed in the first direction or the second direction.

### (Item 20)

The coreless current sensor module according to item 19, wherein
the first bus bar includes a pair of first coupling portions which are respectively coupled to both ends of the pair of first conductor portions, and
the first current sensor is surrounded by the pair of first conductor portions and the pair of first coupling portions as viewed in the first direction or the second direction.

### (Item 21)

The coreless current sensor module according to item 19, wherein the pair of first conductor portions and the first current sensor at least partially overlap with each other as viewed in the first direction or the third direction.

### (Item 22)

The coreless current sensor module according to item 19, wherein the insulator surrounds at least the first current sensor in a spaced-apart state as viewed in the first direction.

### (Item 23)

The coreless current sensor module according to item 1, wherein the support member has a first portion configured integrally with the insulator.

### (Item 24)

The coreless current sensor module according to item 23, wherein the support member further includes a second portion including a substrate on which the first current sensor is mounted.

### (Item 25)

The coreless current sensor module according to item 24, wherein the second portion of the support member is fixed to the first portion of the support member via an adhesive layer.

### (Item 26)

The coreless current sensor module according to item 24, wherein
a surface of the second portion of the support member is a part of the first surface of the support member, and
the insulator is arranged on the first surface of the support member so as to surround the second portion and the first current sensor, spaced apart from the first current sensor, as viewed in the first direction.

### (Item 27)

The coreless current sensor module according to item 26, wherein
the first bus bar includes
a pair of first conductor portions which extend in the second direction and are arranged to face each other with the first current sensor interposed therebetween in a third direction intersecting the second direction along the first surface, and
a pair of first coupling portions which are respectively coupled to both ends of the pair of first conductor portions, and
at least a part of the support member and the insulator are arranged in a through opening of the first bus bar surrounded by the pair of first conductor portions and the pair of first coupling portions.

### (Item 28)

The coreless current sensor module according to item 27, wherein the first current sensor is arranged at a position traversed by a plane passing through centers of the pair of first conductor portions and the pair of first coupling portions in the first direction.

### (Item 29)

The coreless current sensor module according to item 23, wherein the support member is composed of resin together with the insulator.

### (Item 30)

A power module including:
the coreless current sensor module according to any one of items 1 to 29;
an input terminal portion;
an output terminal portion which includes the first bus bar; and
a plurality of power semiconductors which convert direct current input from the input terminal portion to alternating current and output the alternating current to the output terminal portion.

### (Item 31)

A current sensor module including:
a substrate;
a first current sensor which is mounted on a first surface of the substrate and includes at least one magnetoelectric conversion element which outputs a signal corresponding to a magnitude of a magnetic field;
an insulator which surrounds at least the first current sensor with a gap therebetween as viewed in a first direction intersecting the first surface and at least partially overlaps with the first current sensor as viewed in a second direction extending along the first surface;
a first bus bar which is arranged spaced apart from the substrate and through which a current generating a magnetic field detected by the first current sensor flows; and
a magnetism collecting plate which is provided at a position facing a surface of the first current sensor opposite to a surface where the first current sensor is mounted on the substrate, spaced apart from the first current sensor in the first direction, wherein
the insulator is present between the first current sensor and the first bus bar.

### (Item 32)

A current sensor module including:
a substrate;
a first current sensor which is mounted on a first surface of the substrate and includes at least one magnetoelectric conversion element which outputs a signal corresponding to a magnitude of a magnetic field;
an insulator which surrounds at least the first current sensor with a gap therebetween as viewed in a first direction intersecting the first surface and at least partially overlaps with the first current sensor as viewed in a second direction extending along the first surface; a first bus bar which is arranged spaced apart from the substrate and through which a current generating a magnetic field detected by the first current sensor flows;
a second current sensor which is mounted on the first surface of the substrate and includes at least one magnetoelectric conversion element which outputs a signal corresponding to a magnitude of a magnetic field;
a second bus bar which is arranged spaced apart from the substrate and through which a current generating a magnetic field detected by the second current sensor flows; and
a wall portion between the first bus bar and the second bus bar, the wall portion including a magnetic body protruding from the first surface of the substrate, wherein
the insulator is present between the first current sensor and the first bus bar, and
the insulator further surrounds the second current sensor with a gap therebetween as viewed in the first direction, and at least partially overlaps with the second current sensor as viewed in the second direction.

### EXPLANATION OF REFERENCES

10: power module;
20: outer frame;
100: current sensor module;
110: support plate;
110a: surface;
120, 120a, 120b, 120c: bus bar;
121a, 121b, 121c: conductor portion;
122a, 122b, 122c: coupling portion;
125a, 125b, 125c: through opening;
130, 130a, 130b, 130c: insulator;
132, 132a, 132b, 132c: gap;
134a, 134b, 134c: opening;
140, 140a, 140b, 140c: current sensor;
150: substrate;
150a: surface;
160: wall portion;
170a, 170b, 170c: magnetism collecting plate;
180: support member;
182: base;
184: surrounding wall;
200: power semiconductor unit;
202: enclosure; and
220: input terminal portion.

What is claimed is:

1. A coreless current sensor module comprising:
a support member;
a first current sensor which is mounted on a first surface of the support member and includes at least one magnetoelectric conversion element which outputs a signal corresponding to a magnitude of a magnetic field;
an insulator which surrounds at least the first current sensor with a gap therebetween as viewed in a first direction intersecting the first surface and at least partially overlaps with the first current sensor as viewed in a second direction extending along the first surface; and
a first bus bar through which a current generating a magnetic field detected by the first current sensor flows, wherein
at least one of the insulator or the support member is present between the first current sensor and the first bus bar.

2. The coreless current sensor module according to claim 1, wherein
the support member is a substrate,
the first bus bar is arranged spaced apart from the substrate, and
the insulator is present between the first current sensor and the first bus bar.

3. The coreless current sensor module according to claim 2, wherein
a direction intersecting the second direction along the substrate is defined as a third direction, and
the first bus bar at least partially overlaps with the first current sensor as viewed in the first direction or the third direction.

4. The coreless current sensor module according to claim 2, wherein
the first bus bar includes a pair of first conductor portions which extend in the second direction and are arranged to face each other with the first current sensor interposed therebetween in a third direction intersecting the second direction along the substrate, and
the insulator is arranged at least between each of the pair of first conductor portions and the first current sensor, with a gap from the first current sensor.

5. The coreless current sensor module according to claim 4, wherein
the first bus bar includes a pair of first coupling portions which are respectively coupled to both ends of the pair of first conductor portions, and
the first current sensor is surrounded by the pair of first conductor portions and the pair of first coupling portions as viewed in the first direction.

6. The coreless current sensor module according to claim 4, wherein the insulator is further arranged between the substrate and each of the pair of first conductor portions.

7. The coreless current sensor module according to claim 2, wherein the first bus bar and the insulator are in contact with each other.

8. The coreless current sensor module according to claim 5, wherein the insulator is further arranged so as to cover a surface of the first current sensor opposite to a surface where the first current sensor is mounted on the substrate, with a gap from the first current sensor in the first direction.

9. The coreless current sensor module according to claim 5, wherein the insulator has an opening which exposes a surface of the first current sensor opposite to a surface where the first current sensor is mounted on the substrate.

10. The coreless current sensor module according to claim 2, wherein
the first bus bar includes a pair of first conductor portions which extend in a third direction intersecting the second direction along the substrate and are arranged to face each other with the first current sensor interposed therebetween in the first direction, and
the insulator is further arranged between one of the pair of first conductor portions and the first current sensor, with a gap from the first current sensor.

11. The coreless current sensor module according to claim 10, wherein
the first bus bar includes a pair of first coupling portions which are respectively coupled to both ends of the pair of first conductor portions, and
the first current sensor is surrounded by the pair of first conductor portions and the pair of first coupling portions as viewed in the second direction.

12. The coreless current sensor module according to claim 2, further comprising:
a second current sensor which is mounted on the first surface of the substrate and includes at least one magnetoelectric conversion element which outputs a signal corresponding to a magnitude of a magnetic field; and
a second bus bar which is arranged spaced apart from the substrate and through which a current generating a magnetic field detected by the second current sensor flows, wherein
the insulator further surrounds the second current sensor with a gap therebetween as viewed in the first direction, and at least partially overlaps with the second current sensor as viewed in the second direction.

13. The coreless current sensor module according to claim 12, wherein
the first bus bar includes a pair of first conductor portions which extend in the second direction and are arranged to face each other with the first current sensor interposed therebetween in a third direction intersecting the second direction along the first surface,
the second bus bar includes a pair of second conductor portions which extend in the second direction and are arranged to face each other with the second current sensor interposed therebetween in the third direction, and
the insulator is arranged at least between each of the pair of first conductor portions and the first current sensor, with a gap from the first current sensor, and is arranged at least between each of the pair of second conductor portions and the second current sensor, with a gap from the second current sensor.

14. The coreless current sensor module according to claim 13, wherein
the first bus bar includes a pair of first coupling portions which are respectively coupled to both ends of the pair of first conductor portions,
the second bus bar includes a pair of second coupling portions which are respectively coupled to both ends of the pair of second conductor portions,
the first current sensor is surrounded by the pair of first conductor portions and the pair of first coupling portions as viewed in the first direction, and
the second current sensor is surrounded by the pair of second conductor portions and the pair of second coupling portions as viewed in the first direction.

15. The coreless current sensor module according to claim 12, wherein the first current sensor and the second current sensor are arranged side by side in a third direction intersecting the second direction along the substrate.

16. The coreless current sensor module according to claim 12, wherein a portion of the insulator arranged between the first bus bar and the second bus bar includes a portion having a first thickness from the first surface of the substrate and a portion having a second thickness, which is different from the first thickness, from the first surface of the substrate.

17. The coreless current sensor module according to claim 12, wherein
the insulator includes
a first insulator which surrounds the first current sensor with a gap therebetween as viewed in the first direction and at least partially overlaps with the first current sensor as viewed in the second direction, and
a second insulator which surrounds the second current sensor with a gap therebetween as viewed in the first direction and at least partially overlaps with the second current sensor as viewed in the second direction, and
as viewed in the first direction, a gap is provided at least partially between the first insulator and the second insulator.

18. The coreless current sensor module according to claim 2, wherein a spacing between the first current sensor and the first bus bar is more than 0 mm and equal to or less than 5 mm.

19. A coreless current sensor module comprising:
a substrate;
a first current sensor which is mounted on a first surface of the substrate and includes at least one magnetoelectric conversion element which outputs a signal corresponding to a magnitude of a magnetic field;
a first bus bar which includes a pair of first conductor portions which extend in a second direction extending along the substrate or in a third direction intersecting the second direction along the substrate and are arranged to face each other with the first current sensor interposed therebetween as viewed in a first direction intersecting the substrate or in the second direction, and is arranged spaced apart from the substrate, and through which a current generating a magnetic field detected by the first current sensor flows; and
an insulator which is arranged at least between the pair of first conductor portions and the first current sensor, with a gap from the first current sensor, as viewed in the first direction or the second direction.

20. The coreless current sensor module according to claim 19, wherein
the first bus bar includes a pair of first coupling portions which are respectively coupled to both ends of the pair of first conductor portions, and
the first current sensor is surrounded by the pair of first conductor portions and the pair of first coupling portions as viewed in the first direction or the second direction.

21. The coreless current sensor module according to claim 19, wherein
the pair of first conductor portions and the first current sensor at least partially overlap with each other as viewed in the first direction or the third direction.

22. The coreless current sensor module according to claim 19, wherein the insulator surrounds at least the first current sensor in a spaced-apart state as viewed in the first direction.

23. The coreless current sensor module according to claim 1, wherein the support member has a first portion configured integrally with the insulator.

24. The coreless current sensor module according to claim 23, wherein the support member further includes a second portion including a substrate on which the first current sensor is mounted.

25. The coreless current sensor module according to claim 24, wherein the second portion of the support member is fixed to the first portion of the support member via an adhesive layer.

26. The coreless current sensor module according to claim 24, wherein
a surface of the second portion of the support member is a part of the first surface of the support member, and
the insulator is arranged on the first surface of the support member so as to surround the second portion and the first current sensor, spaced apart from the first current sensor, as viewed in the first direction.

27. The coreless current sensor module according to claim 26, wherein
the first bus bar includes
a pair of first conductor portions which extend in the second direction and are arranged to face each other with the first current sensor interposed therebetween in a third direction intersecting the second direction along the first surface, and
a pair of first coupling portions which are respectively coupled to both ends of the pair of first conductor portions, and
at least a part of the support member and the insulator are arranged in a through opening of the first bus bar surrounded by the pair of first conductor portions and the pair of first coupling portions.

28. The coreless current sensor module according to claim 27, wherein the first current sensor is arranged at a position traversed by a plane passing through centers of the pair of first conductor portions and the pair of first coupling portions in the first direction.

29. The coreless current sensor module according to claim 23, wherein the support member is composed of resin together with the insulator.

30. A power module comprising:
the coreless current sensor module according to claim 1;
an input terminal portion;
an output terminal portion which includes the first bus bar; and
a plurality of power semiconductors which convert direct current input from the input terminal portion to alternating current and output the alternating current to the output terminal portion.

31. A current sensor module comprising:
a substrate;
a first current sensor which is mounted on a first surface of the substrate and includes at least one magnetoelectric conversion element which outputs a signal corresponding to a magnitude of a magnetic field;
an insulator which surrounds at least the first current sensor with a gap therebetween as viewed in a first direction intersecting the first surface and at least partially overlaps with the first current sensor as viewed in a second direction extending along the first surface;
a first bus bar which is arranged spaced apart from the substrate and through which a current generating a magnetic field detected by the first current sensor flows; and
a magnetism collecting plate which is provided at a position facing a surface of the first current sensor opposite to a surface where the first current sensor is mounted on the substrate, spaced apart from the first current sensor in the first direction, wherein
the insulator is present between the first current sensor and the first bus bar.

32. A current sensor module comprising:
a substrate;
a first current sensor which is mounted on a first surface of the substrate and includes at least one magnetoelectric conversion element which outputs a signal corresponding to a magnitude of a magnetic field;
an insulator which surrounds at least the first current sensor with a gap therebetween as viewed in a first direction intersecting the first surface and at least partially overlaps with the first current sensor as viewed in a second direction extending along the first surface;
a first bus bar which is arranged spaced apart from the substrate and through which a current generating a magnetic field detected by the first current sensor flows;
a second current sensor which is mounted on the first surface of the substrate and includes at least one magnetoelectric conversion element which outputs a signal corresponding to a magnitude of a magnetic field;
a second bus bar which is arranged spaced apart from the substrate and through which a current generating a magnetic field detected by the second current sensor flows; and
a wall portion between the first bus bar and the second bus bar, the wall portion including a magnetic body protruding from the first surface of the substrate, wherein
the insulator is present between the first current sensor and the first bus bar, and
the insulator further surrounds the second current sensor with a gap therebetween as viewed in the first direction, and at least partially overlaps with the second current sensor as viewed in the second direction.
